(19) United States
(12) Patent Application Publication
(10) Pub. No.: US 2007/0103961 A1
(43) Pub. Date: May 10, 2007

(54) RAM cell with soft error protection using ferroelectric material

(75) Inventors: Weston Roper, Shakopee, MN (US); Cheisan Yue, Roseville, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/268,006

(22) Filed: Nov. 7, 2005

(51) Int. Cl. G11C 11/22

(52) U.S. Cl. 365/145; 365/154

(57) ABSTRACT

A static random access memory (SRAM) cell with single event and soft error protection using ferroelectric material is presented. The SRAM cell comprises two inverters in a mutual feedback loop, with the output of each of the inverters coupled to the input of the other. A ferroelectric capacitor is coupled to the output of one of the inverters in order to induce an RC delay and provide single event upset (SEU), single event effect (SEE), single event transient (SET), and soft error protection. In addition, a method is presented where ferroelectric capacitor of the system is fabricated after the underlayers of the SRAM cell have been implemented in order to avoid substantial changes to standard underlayer processing.

### FIELD

The present invention relates to the field of static random access memory cells. More specifically, the present invention relates to static random access memory cells that comprise six transistors and are radiation hardened to achieve single event upset and soft error immunity using ferroelectric materials.

### BACKGROUND

Single events and soft errors in circuits are the result of high energy particles interacting with and causing changes to the electrical states in certain electrical components. These phenomena are generally temporally and spatially random, although the effect that they have on a given circuit may be affected by the physical and electrical characteristics of the circuit. In general, as circuits scale down to smaller sizes they are more susceptible to single events and soft errors, due largely to reductions in drive currents and voltages which lead to smaller noise margins. At the 65 nm technology node and below, the high leakage currents that are expected with standard complementary metal oxide semiconductor (CMOS) circuits increases this susceptibility.

In memory cells, the results of single events and soft errors may be a change in the stored value. Specifically, a high-energy particle interacting with a node at a low electrical state may cause the node to jump to a high electrical state. In a dynamic random access memory (DRAM) cell, this increase in energy may easily change the value on the capacitive storage node. In a static random access memory (SRAM) cell comprising dual-feedback inverters, the interaction of high-energy particles may be sufficient to interrupt the feedback loop and drive the normally stable device to invert its stored binary state. Although hardening DRAM cells against single event and soft error phenomena is generally performed outside of the memory cell circuit, hardening of SRAM cells has generally been accomplished by altering the feedback properties of the cell so that an upset occurring at only one node will not propagate through the entire latch.

In a general SRAM cell comprising two inverters formed by CMOS logic, one method for hardening the circuit by altering the feedback may be through increasing the RC delay of one of the feedback nodes. FIG. 1ashows a gate-level schematic of an SRAM cell according to the prior art, where the cell is comprised of two inverters 102, 104 configured into a feedback loop. The output of the first inverter 102 is coupled to the input of the second inverter 104, and the output of the second inverter 104 is coupled to the input of the first inverter 102 . The outputs of the first and second inverter are coupled to true and complementary bit lines, respectively, through write control switches 114, 116. Due to the feedback loop and the gain of the CMOS inverters, the SRAM cell can store a bit value and its complement as long as power is supplied to the two voltage rails.

FIG. 1bshows a transistor-level schematic of the dual-inverter SRAM cell, where the inverters are implemented using CMOS logic. Each inverter comprises a matched pair of p-type metal oxide semiconductor (PMOS) transistors and n-type metal oxide semiconductor (NMOS) transistors. The source node of each PMOS device 106, 110 is coupled to a supply voltage rail, while the source node of each NMOS device 108, 112 is coupled to an electrical ground rail. For each inverter, the corresponding PMOS and NMOS gates are coupled to the inverter input while the drains are coupled to the inverter output.

As discussed above, the standard SRAM cell may be radiation hardened by augmenting one of the feedback loops with resistive or capacitive loads to create additional RC delay. FIG. 2 shows a schematic of a SRAM cell according to the prior art where an RC delay is induced through one of the feedback paths through the use of a resistor-capacitor pair 118, 120. The resistor 118 and capacitor 120 combine with any interconnect resistances and parasitic capacitances to provide a propagation signal delay that is proportional to the product of their respective resistance and capacitance. In other radiation-hardened designs, active components such as diodes and transistors may be used in place of these passive elements to more appropriately increase the delay. However, the addition of multiple passive and active device components may generally cause the size of the standard SRAM cell to increase, resulting in lower manufacturing yields and higher production costs.

As a result, it would be desirable to design a SRAM cell that is protected against single event and soft error phenomena and that also requires as small of an increase in memory cell area as possible. Furthermore, it would be desirable for any modified SRAM cell designs to require few, if any, additional processing steps.

### BRIEF DESCRIPTION OF THE DRAWINGS

Exemplary embodiments of the invention are described below in conjunction with the appended figures, wherein like reference numerals refer to like elements in the various figures, and wherein:

FIG. 1 is a gate-level and transistor-level schematic of a dual inverter SRAM cell according to the prior art;

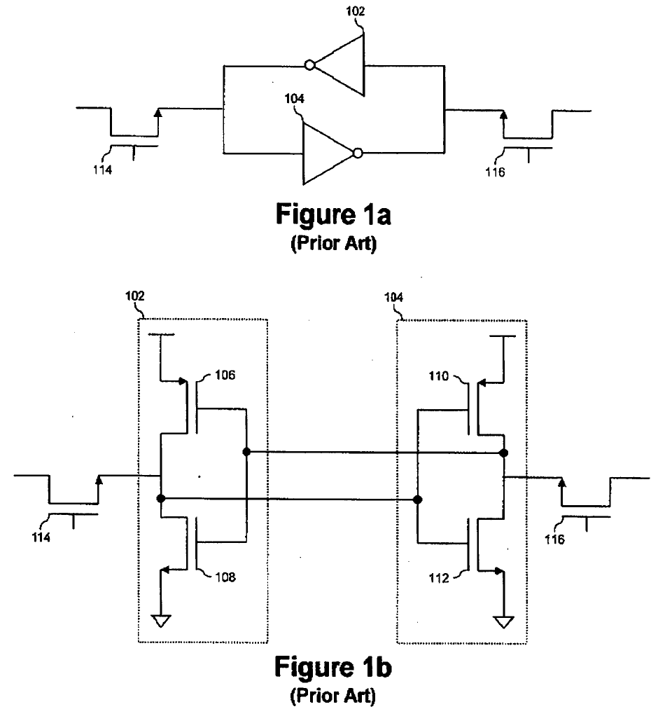

FIG. 2 is a transistor-level schematic of a dual inverter SRAM cell having resistive and capacitive elements to induce an RC delay in the feedback loop of the latch, according to the prior art;

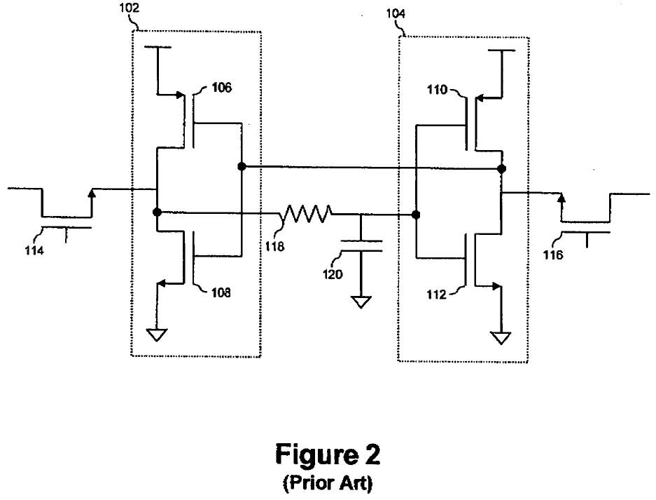

FIG. 3 is a transistor-level schematic of a six-transistor dual-inverter SRAM cell with a ferroelectric capacitor for single event and soft error protection, according to an exemplary embodiment; and

FIG. 4 is a transistor-level schematic of a six-transistor dual-inverter SRAM cell with a ferroelectric capacitor and CMOS transistors having varying gate oxide thicknesses according to an exemplary embodiment.

### DETAILED DESCRIPTION

1. Invention Overview

Much development in memory systems has been directed towards an increase in both the performance and capabilities of individual memory cells. The development of ferroelectric materials has led to new methods for improving both DRAM and SRAM devices. Due to their generally high dielectric constants and large resistance, ferroelectric materials are ideally suited as dielectric layers in capacitors. The high dielectric constant of ferroelectric materials results in capacitors of a given capacitance requiring a smaller overall area than those utilizing general oxide dielectrics. As a result, ferroelectric capacitors have been utilized in single-transistor single-capacitor (1T1C) DRAM cells to reduce the memory cell size, as well as in SRAM cells to increase the speed of the cell. In 1T1C DRAM cells, ferroelectric capacitors have been used to implement the storage capacitor. In SRAM cells, ferroelectric capacitors have been coupled to write lines as shadow capacitors in order to increase the drive and speed of the memory cell. However, the integration of ferroelectric devices, especially capacitors, has generally been limited to these applications.

The current invention takes advantage of the reduced size of ferroelectric capacitors in order to implement an SRAM cell with protection against soft errors and single event effects, such as single event upsets (SEU), single event effects (SEE), and single event transients (SET). The design comprises a dual-inverter SRAM cell with a ferroelectric capacitor coupled to the input of one of the inverters. The RC delay that results from the ferroelectric capacitor helps to reduce the adverse effects of bombardment by high-energy particles. Additionally, the use of ferroelectric material allows the capacitor to attain a high-capacitive value without the consumption of relatively large amounts of area. The design thereby allows a radiation-hardened cell to be implemented without sacrificing the optimization of memory cell area.

2. Memory Cell Design and Operation

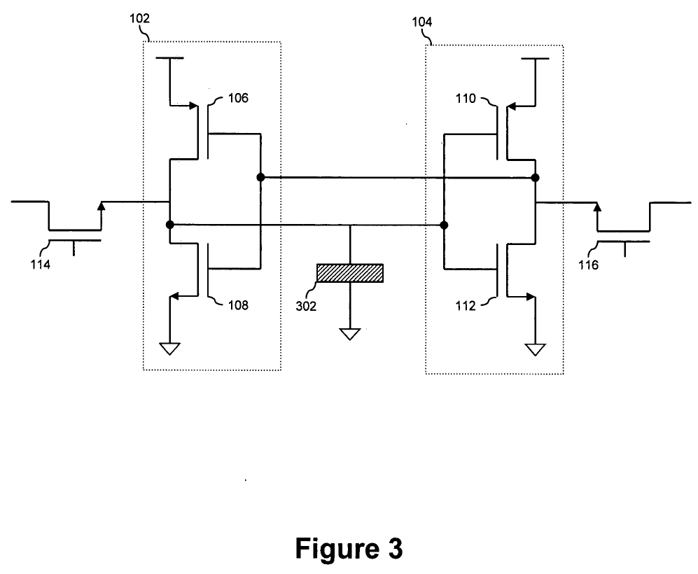

FIG. 3 shows a dual-inverter memory cell with a ferroelectric capacitor according to an exemplary embodiment. The basic SRAM cell comprises a first inverter and a second inverter in a dual-feedback or latch formation, where the output of the first inverter 102 is coupled to the input of the second inverter 104 and the output of the second inverter 104 is coupled to the first inverter 102. Because of the positive gain of the inverter circuits, the memory cell is able to hold a binary value and its complement as long as power is supplied to the first and second inverters. Connected to the input of the first inverter may be a first switch 114 that selectively couples the input of the first inverter 102 to a true bit line, and connected to the input of the second inverter may be a second switch 116 that selectively couples the input of the second inverter 104 to a complementary bit line. The first switch and second switch may both be controlled by a word line signal. Additionally, the true bit line and complement bit line may both be driven by a precision current driver. Each of these switches may be implemented by an n-type metal oxide semiconductor (NMOS) transistor.

A read operation may be performed on the memory cell by charging both the true bit line and the complement line. Once both lines are charged the word line signal may be enabled, thereby electrically coupling the storage nodes of the latch to the word lines. During the read operation the bit lines will then be pulled to the state stored on their respective nodes of the cell. A write operation may be performed on the memory cell by first charging the true bit line and the complement bit line to the desired complimentary states, and then enabling the first and second switches by driving the word line signal. The voltages charged on the bit lines will then drive the latch component of the memory cell to store the desired binary value and its compliment.

According to one embodiment of the invention, coupled to the output of the first inverter (and the input of the second inverter) may be a ferroelectric capacitor 302. The ferroelectric capacitor may be a parallel plate capacitor with ferroelectric material comprising the central spacing, or dielectric layer. The ferroelectric material may be any type of ferroelectric or other pyroelectric material in which the spontaneous polarization can be reoriented between equilibrium states by applying an electric field. The dielectric material may be lead zirconium titanate (PbZrₓTi₁₋ₓO₃), strontium bismuth tantalite (SrBi₂Ta₂O₉), bismuth lanthanum titanate (Bi₄₋ₓLaₓTiO₁₂), or other type of ferroelectric material. One plate of the ferroelectric capacitor 302 may be connected to the output of the first inverter, with the second plate being connected to a reference voltage rail, such as the electrical ground rail. The ferroelectric capacitor 302 may induce a delay in the feedback loop between the output of the second inverter 104 and the input of the first inverter 102, thereby creating an imbalance in the propagation delay of the latch circuit that disrupts the race condition caused by a high-energy particle collision. As a result, the memory cell will not flip states. The ferroelectric capacitor 302 may be created after the underlayers of the memory cell have already been fabricated, where the underlayers generally consist of those components fabricated at a lower level than the metallization layers. In an SRAM memory cell, the device components fabricated in the underlayer processes may comprise any doped substrate regions, transistor gate dielectrics, and polysilicon gates. The ferroelectric capacitor 302 may then be fabricated with the subsequent metallization layers, and with a separate masking step being utilized to deposit the ferroelectric dielectric material. As a result, the plates of the ferroelectric capacitor 302 may be comprised of the same metals used for the manufacture of the memory cell at a given metallization step, such as the interconnect metals aluminum and copper.

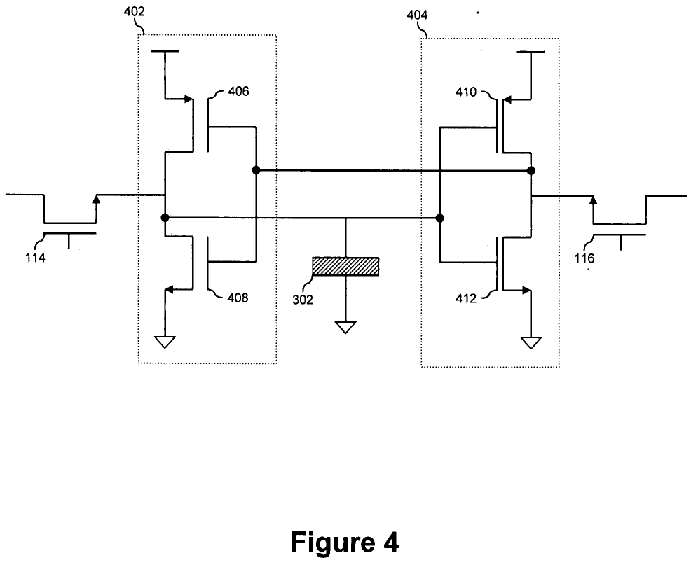

Additionally, the effect of the capacitor in disrupting the effects of high-energy particle collisions may be augmented by altering the threshold voltage of the transistors in the first inverter with respect to the second inverter. FIG. 4 shows a memory cell in which the respective threshold of the two inverters has been modified by adjusting the respective gate oxide thicknesses of the devices that comprise the inverters. By increasing the thickness of the oxide of the PMOS transistor 406 and NMOS transistor 408 in the first inverter, the threshold voltages of these devices are increased. As a result, the ability of the first inverter to drive the second inverter is substantially decreased. This helps to prevent loosely driven nodes, or nodes affected by a single event, from changing the master node. The gate oxide thickness of the thick oxide PMOS 406 and the thick oxide NMOS 408 may substantially be twice the thickness of their thin oxide PMOS 410 and NMOS 412 counterparts in the other inverter. Altering the gate oxide thicknesses for each of these components may require few, if any, additional processing steps.

Exemplary embodiments of the present invention relating to a memory cell with single event and soft error protection using ferroelectric materials have been illustrated and described. It should be noted that more significant changes in configuration and form are also possible and intended to be within the scope of the system taught herein. For example, the ferroelectric capacitor may likewise be coupled to the output of the second inverter rather than the first inverter. In addition, the transistors of the second inverter may be thick-oxide transistors with the transistors of the first inverter being thin-oxide transistors consistent with the descriptions of such devices provided above. In addition, the inverters and latches of the SRAM cell may be implemented with other devices than CMOS devices.

Unless otherwise indicated in the description, the accompanying figures are not drawn to scale and should not be interpreted as such. For example, where it is not otherwise indicated the relative sizes of transistors are not to be taken from the figures nor are the specific lengths and routings of interconnects, and the figures are not intended to be limiting in this respect.

In view of the wide variety of embodiments to which the principles of the present invention can be applied, it should be understood that the illustrated embodiments are exemplary only, and should not be taken as limiting the scope and spirit of the present invention. Additionally, the claims should not be read as limited to the described order or elements unless stated to that effect.

1. A static random access memory (SRAM) cell comprising:
a first and second inverter each having an input and output, wherein the output of the first inverter is coupled to the input of the second inverter and the output of the send inverter is coupled to the input of the first inverter; and
a ferroelectric capacitor having a first plate coupled to the output of the second inverter and a second plate coupled to a static reference voltage.

2. The SRAM cell of claim 1 further comprising:
a first switch that selectively couples the output of the first inverter to a true bit line; and
a second switch that selectively couples the output of the second inverter to a complement bit line.

3. The SRAM cell of claim 2 wherein the first switch and the second switch each comprise an n-type metal oxide semiconductor (NMOS) transistor.

4. The SRAM cell of claim 1 wherein the first and second inverters each comprise a complementary metal oxide semiconductor (CMOS) inverter.

5. The SRAM cell of claim 4 wherein the CMOS inverter comprises:
a p-type metal oxide semiconductor (PMOS) transistor that has a PMOS source coupled to a first reference voltage, a PMOS drain coupled to the inverter output, and a PMOS gate coupled to the inverter input; and
an n-type metal oxide semiconductor (NMOS) transistor that has an MMOS source coupled to a second reference voltage, an NMOS drain coupled to the inverter output, and an NMOS gate coupled to the inverter input.

6. The SRAM cell of claim 5 wherein the first inverter has a diminished drive capability compared to the second inverter.

7. The SRAM cell of claim 6 wherein the PMOS transistor and the NMOS transistor of the first inverter each comprise a substantially thick gate oxide, and wherein the PMOS transistor and the NMOS transistor of the second inverter each comprise a substantially thin gate oxide.

8. The SRAM cell of claim 6 wherein the thick gate oxide of both the PMOS transistor and the NMOS transistor of the first inverter is substantially twice the thickness of the thin gate oxide of the PMOS transistor and the NMOS transistor of the second inverter.

9. The SRAM cell of claim 5 wherein the second reference voltage is electrical ground.

10. The SRAM cell of claim 1 wherein the ferroelectric capacitor comprises a dielectric material of lead zirconium titanate (PbZrxTi1-xO3).

11. The SRAM cell of claim 1 wherein the ferroelectric capacitor comprises a dielectric material of strontium bismuth tantalite (SrBi2Ta2O9).

12. The SRAM cell of claim 1 wherein the ferroelectric capacitor comprises a dielectric material of bismuth lanthanum titanate (Bi4-xLaxTiO12).

13. A process for creating a static random access memory (SRAM) cell having a ferroelectric capacitor comprising:
fabricating an underlayer comprising a first inverter and a second inverter, wherein output of the second inverter is coupled to the input of the first inverter; and
fabricating a ferroelectric capacitor having a first plate that is coupled to the input of the first inverter, and having a second plate that is coupled to a static reference voltage, and wherein the ferroelectric capacitor is fabricated after fabricating the underlayer.

14. The process of claim 13 wherein fabricating the ferroelectric capacitor comprises:
depositing a bottom electrode layer;
depositing a ferroelectric layer; and
depositing a top electrode layer.

15. The process of claim 13 wherein the ferroelectric layer comprises lead zirconium titanate (PbZrxTi1-xO3).

16. The process of claim 13 wherein the ferroelectric layer comprises strontium bismuth tantalite (SrBi2Ta2O9).

17. The process of claim 13 wherein the ferroelectric layer comprises bismuth lanthanum titanate (Bi4-xLaxTiO12).

18. The process of claim 13 wherein the underlayer comprises first and second control switches, wherein the first control switch selectively couples the input of the first inverter to a true bit line, and wherein the second control switch selectively couples the input of the second inverter to a complementary bit line.
